(19) United States
(12) Patent Application Publication
(10) Pub. No.: US 2026/0097660 A1
(43) Pub. Date: Apr. 9, 2026

(54) Power Feeder

(71) Applicant: Daifuku Co., Ltd., Osaka-shi (JP)

(72) Inventor: Tomoaki Nishikawa, Hinocho (JP)

(21) Appl. No.: 19/347,979

(22) Filed: Oct. 2, 2025

(30) Foreign Application Priority Data
Oct. 3, 2024 (JP) 2024-174070

(51) Int. Cl. B60L 13/03; H02J 50/10; H02J 50/40

(52) U.S. Cl. CPC B60L 13/03; H02J 50/10; H02J 50/402; B60L 2200/26; B60L 2210/30

(57) ABSTRACT

A power feeder includes a feed line extending along a travel path for movable bodies to power to the movable bodies, a power supply device connected to the feed line to supply power to the feed line, and a control system that controls the power supply device. The control system includes a count obtainer that obtains count information indicating the number of movable bodies in a power feed area in which the feed line is disposed in the travel path, and a controller that performs, based on the count information, variable power control to reduce power from the power supply device to the feed line in response to a decrease in the number of movable bodies in the power feed area and to increase power from the power supply device to the feed line in response to an increase in the number of movable bodies in the power feed area.

### CROSS-REFERENCE TO RELATED APPLICATION

This application claims priority to Japanese Patent Application No. 2024-174070 filed October 3, 2024, the disclosure of which is hereby incorporated by reference in its entirety.

### BACKGROUND OF THE INVENTION

### Field of the Invention

The present invention relates to a power feeder including a feed line extending along a travel path for multiple movable bodies to feed power to the multiple movable bodies and a power supply device connected to the feed line to supply power to the feed line.

### Description of the Related Art

An example of such a power feeder is described in Japanese Unexamined Patent Application Publication No. 2002-67747 (hereafter, JP 2002-67747). In the background described hereafter, reference signs in parentheses are the reference signs in JP 2002-67747.

The power feeder in JP 2002-677471 includes multiple feed lines (47) extending along a travel path (B) for multiple movable bodies (V). Each of the multiple feed lines (47) is connected to a power supply device (M). Each of the movable bodies (V) receives power from an adjacent feed line (47) to move along the travel path (B).

In the power feeder in JP 2002-67747, power supplied from each power supply device (M) to the corresponding feed line (47) is set based on the maximum number of movable bodies (V) that can be in a single power feed area in which the feed lines (47) are arranged on the travel path (B). The power supply device (M) may thus supply excess power to the corresponding feed line (47), increasing the power consumption of the power feeder.

### SUMMARY OF THE INVENTION

One or more aspects are directed to a power feeder that consumes less power.

In response to the above, a power feeder includes at least one feed line extending along a travel path for a plurality of movable bodies to feed power to the plurality of movable bodies, at least one power supply device connected to the at least one feed line to supply power to the at least one feed line, and at least one control system that controls the at least one power supply device. The at least one control system includes a count obtainer that obtains count information indicating a number of movable bodies in at least one power feed area that is an area in which the at least one feed line is disposed in the travel path, and a controller that performs, based on the count information, variable power control to reduce power supplied from the at least one power supply device to the at least one feed line in response to a decrease in the number of movable bodies in the at least one power feed area and to increase power supplied from the at least one power supply device to the at least one feed line in response to an increase in the number of movable bodies in the at least one power feed area.

In this structure, when the number of movable bodies in the power feed area increases or decreases, power supplied from the power supply device to the feed line can be appropriately adjusted through the variable power control. The structure allows the power feeder to consume less power than, for example, a structure in which power supplied from the power supply device to the feed line is set based on the maximum number of movable bodies that can be in the power feed area.

### BRIEF DESCRIPTION OF THE DRAWINGS

FIG. 1 is a plan view of an article transport facility including a power feeder according to an embodiment.

FIG. 2 is a front view of a movable body in the embodiment.

FIG. 3 is a schematic diagram of the power feeder according to the embodiment.

FIG. 4 is a flowchart of an example control process performed by a control system.

FIG. 5 is a table of example first thresholds and example second thresholds.

FIG. 6 is a flowchart of an example control process performed by a movable body control system.

FIG. 7 is a table of an example first limit and an example second limit for each number of power supplies in operation.

### DESCRIPTION OF THE INVENTION

A power feeder 100 according to an embodiment will be described below with reference to the drawings. In the present embodiment, the power feeder 100 is installed in an article transport facility 200.

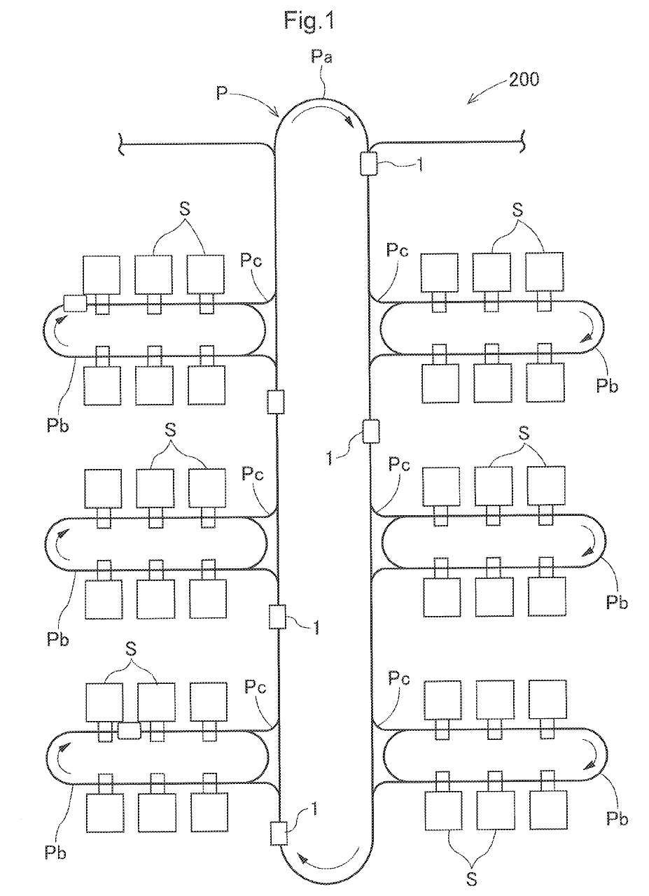

As shown in FIG. 1, the article transport facility 200 includes multiple movable bodies 1 that move along a travel path P. In the present embodiment, each movable body 1 is a transport vehicle that transports an article. The article is, for example, a front opening unified pod (FOUP) containing semiconductor substrates or a glass substrate to be used as a material for displays.

In the present embodiment, the travel path P includes a looped primary path Pa, multiple looped secondary paths Pb each extending through multiple stations S, and multiple connecting paths Pc connecting the primary path Pa and the secondary paths Pb.

Each station S allows a movable body 1 to stop at a position corresponding to the station S and to, for example, transfer an article between the station S and the movable body 1. At each station S, an article is transferred to and from, for example, a load port of a processing device that processes the article, a loading and unloading port of a storage device for storing the article, or a storage shelf for temporarily storing the article.

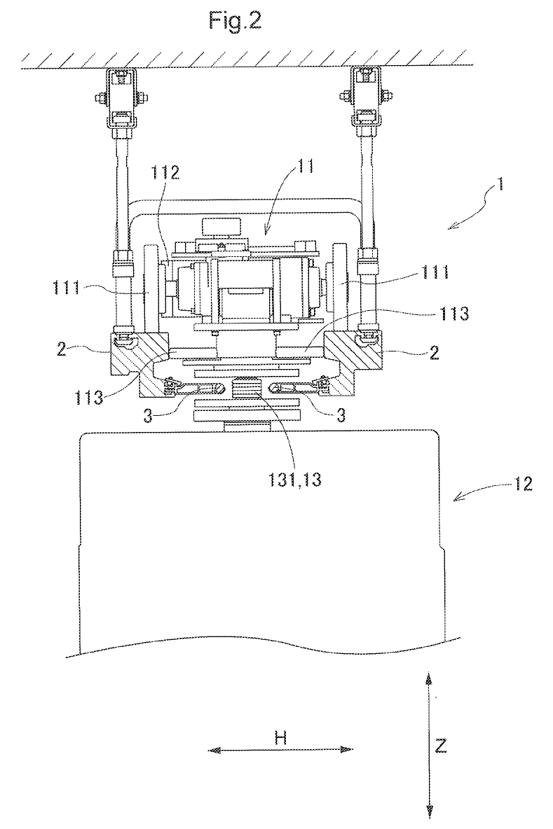

In the present embodiment, the article transport facility 200 further includes a pair of travel rails 2 hung from the ceiling as shown in FIG. 2. The pair of travel rails 2 extend along the travel path P. The pair of travel rails 2 are arranged at a predetermined distance from each other in a path width direction H perpendicular to the travel path P as viewed vertically, or more specifically, in a vertical direction Z parallel to the direction of gravity. In the present embodiment, each of the multiple movable bodies 1 is a ceiling-hung transport vehicle that travels along the travel path P as being guided along the pair of travel rails 2.

In the present embodiment, each of the multiple movable bodies 1 includes a traveler 11 and a transferrer 12.

The traveler 11 includes multiple travel wheels 111 and a travel motor 112. The travel wheels 111 roll on the upper surfaces of the pair of travel rails 2 that serve as traveling surfaces. The travel motor 112 drives at least one of the travel wheels 111 to rotate.

In the present embodiment, the traveler 11 further includes multiple guide wheels 113. The guide wheels 113 are supported in a manner rotatable about an axis extending in the vertical direction Z. The guide wheels 113 are separated in the path width direction H to be in contact with a pair of inner side surfaces of the pair of travel rails 2 facing in the path width direction H.

The transferrer 12 transfers an article to and from the stations S. Although not described in detail, the transferrer 12 includes, for example, a holder, a lift, a horizontal mover, and a rotator. The holder holds an article. The lift lifts and lowers the holder relative to the traveler 11. The horizontal mover moves the holder horizontally relative to the traveler 11. The rotator rotates the holder about a rotation axis extending in the vertical direction Z relative to the traveler 11. The transferrer 12 may have any structure appropriate for transferring an article to and from the stations S and is not limited to the structure described above.

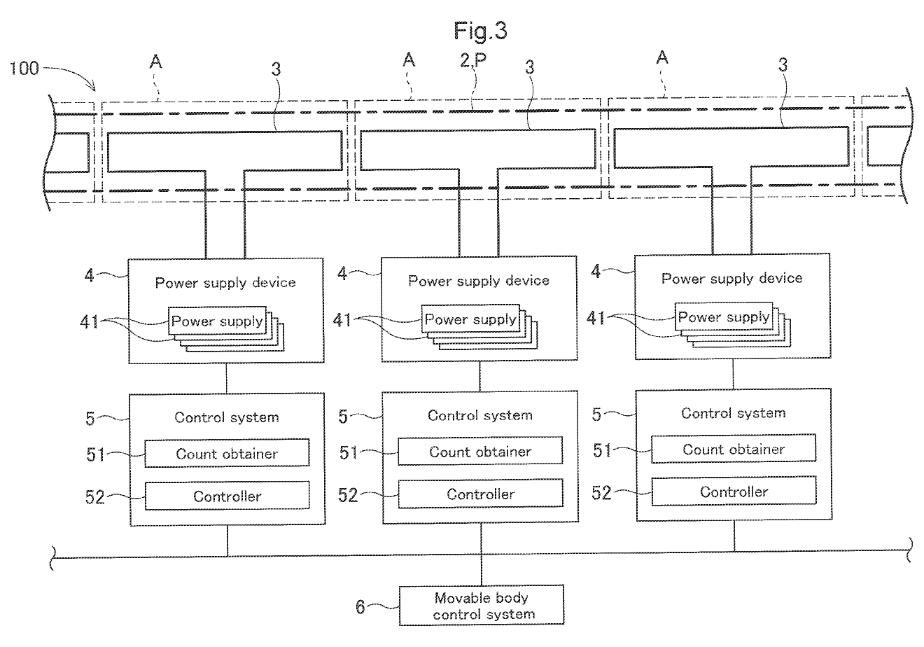

As shown in FIG. 3, the power feeder 100 includes feed lines 3, power supply devices 4, and control systems 5. In the present embodiment, the power feeder 100 further includes a movable body control system 6.

The feed lines 3 extend along the travel path P for the multiple movable bodies 1. The feed lines 3 feed power to the movable bodies 1. In the present embodiment, multiple feed lines 3 extend along the travel path P.

In the present embodiment, each movable body 1 further includes a power receiver 13 as shown in FIG. 2. The power receiver 13 receives power from the feed lines 3 contactlessly. In the present embodiment, the feed lines 3 are supported by the pair of travel rails 2 to be adjacent to the opposite sides of the power receiver 13 in the path width direction H.

The power receiver 13 includes a pickup coil 131. In the pickup coil 131, alternating current power is induced by a magnetic field generated around the feed lines 3 receiving alternating current. The alternating current power is converted to direct current by a power receiving circuit in the power receiver 13 including, for example, a rectifier circuit and a smoothing capacitor, and is supplied to, for example, the travel motor 112 in the movable body 1 and various actuators.

As shown in FIG. 3, the power supply devices 4 are connected to the feed lines 3 to supply power to the feed lines 3. In the present embodiment, multiple power supply devices 4 are connected to the multiple feed lines 3. More specifically, to connect one power supply device 4 to one feed line 3, as many power supply devices 4 as the feed lines 3 are arranged in the present embodiment.

In the present embodiment, each power supply device 4 includes N power supplies 41 (N is an integer greater than or equal to 2). Each of the N power supplies 41 supplies power to the feed line 3. In this example, each power supply device 4 includes four power supplies 41 (N = 4).

The control systems 5 control the power supply devices 4. In the present embodiment, multiple control systems 5 control the multiple power supply devices 4. More specifically, to cause one control system 5 to control one power supply device 4, as many control systems 5 as the power supply devices 4 are arranged in the present embodiment.

Each control system 5 includes a count obtainer 51. The count obtainer 51 obtains count information indicating a number X of movable bodies that is the number of movable bodies 1 in a power feed area A. In the present embodiment, the count obtainer 51 obtains the count information indicating the number X of movable bodies from the movable body control system 6. The power feed area A herein is an area in the travel path P in which a feed line 3 is disposed. In the present embodiment, multiple power feed areas A are defined to correspond to the respective multiple feed lines 3.

The movable body control system 6 controls the multiple movable bodies 1. In the present embodiment, the movable body control system 6 stores the number X of movable bodies for each of the multiple feed lines 3.

Each control system 5 includes a controller 52. The controller 52 performs variable power control. The variable power control reduces power supplied from the power supply device 4 to the feed line 3 in response to a decrease in the number of movable bodies 1 in the power feed area A and increases power supplied from the power supply device 4 to the feed line 3 in response to an increase in the number of movable bodies 1 in the power feed area A based on the count information indicating the number X of movable bodies. Multiple movable bodies 1 enter or exit the power feed area A. The number of movable bodies 1 in the power feed area A increases or decreases accordingly. In the present embodiment, multiple movable bodies 1 move through multiple power feed areas A. The number of movable bodies 1 in each power feed area A thus increases or decreases.

In the present embodiment, each controller 52 increases or reduces a number Na of power supplies in operation in the variable power control to increase or reduce power supplied from the power supply device 4 to the feed line 3. The number Na of power supplies in operation herein is the number of power supplies 41 that are supplying power to the feed line 3 among the N power supplies 41.

In the present embodiment, the controllers 52 in the multiple control systems 5 perform the variable power control independently of one another.

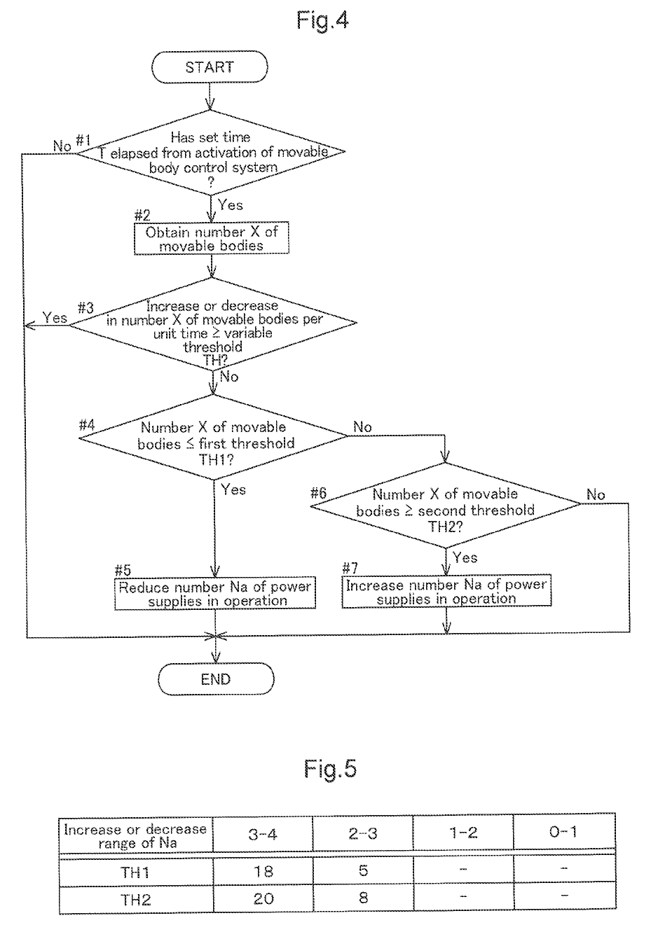

A control process performed by the controller 52 in each control system 5 will be described below with reference to FIG. 4. FIG. 4 is a flowchart of an example control process performed by the controller 52.

As shown in FIG. 4, the controller 52 first determines whether a predetermined set time T has elapsed from the activation of the movable body control system 6 (step #1). When the set time T has not elapsed from the activation of the movable body control system 6 (No in step #1), the controller 52 ends the control process. The set time T is set to allow the movable body control system 6 to determine the number X of movable bodies appropriately.

When the set time T has elapsed from the activation of the movable body control system 6 (Yes in step #1), the controller 52 obtains the count information indicating the number X of movable bodies from the movable body control system 6 (step #2).

The controller 52 then determines whether an increase or a decrease in the number of movable bodies 1 per unit time in the power feed area A (hereafter referred to as a target power feed area A) including the feed line 3 connected to the power supply device 4 to be controlled by the controller 52 is greater than or equal to a predetermined variable threshold TH (step #3). When an increase or a decrease in the number of movable bodies 1 per unit time in the target power feed area A is greater than or equal to the variable threshold TH (Yes in step #3), the controller 52 ends the control process.

When an increase or a decrease in the number of movable bodies 1 per unit time in the target power feed area A is less than the variable threshold TH (No in step #3), the controller 52 performs the variable power control (refer to steps #4 to #7 described later).

In this example, as described above, the controller 52 does not perform the variable power control until the set time T elapses from the activation of the movable body control system 6. The controllers 52 in the multiple control systems 5 do not perform the variable power control in any of the multiple power feed areas A in which an increase or a decrease in the number of movable bodies 1 per unit time is greater than or equal to the variable threshold TH. One or more power feed areas A in which an increase or a decrease in the number of movable bodies 1 per unit time is greater than or equal to the variable threshold TH may be identified in advance by, for example, simulation, and the variable power control may not be performed in these power feed areas A.

Subsequently, the controller 52 determines whether the number X of movable bodies in the target power feed area A is less than or equal to a predetermined first threshold TH1 (step #4). When the number X of movable bodies in the target power feed area A is less than or equal to the first threshold TH1 (Yes in step #4), the controller 52 reduces the number Na of power supplies in operation (step #5), and then ends the control process.

When the number X of movable bodies in the target power feed area A is greater than the first threshold TH1 (No in step #4), the controller 52 determines whether the number X of movable bodies in the target power feed area A is greater than or equal to a predetermined second threshold TH2 (step #6).

When the number X of movable bodies in the target power feed area A is greater than or equal to the second threshold TH2 (Yes in step #6), the controller 52 increases the number Na of power supplies in operation (step #7), and then ends the control process. When the number X of movable bodies in the target power feed area A is less than the second threshold TH2 (No in step #6), the controller 52 ends the control process.

In this example, as described above, the controller 52 in the variable power control reduces power supplied from the power supply device 4 to the feed line 3 in response to the number of movable bodies 1 in the power feed area A being less than or equal to the first threshold TH1 and increases power supplied from the power supply device 4 to the feed line 3 in response to the number of movable bodies 1 in the power feed area A being greater than or equal to the second threshold TH2. The first threshold TH1 herein is less than the second threshold TH2.

In the example shown in FIG. 5, the first threshold TH1 and the second threshold TH2 are respectively set to 18 and 20 when the controller 52 increases or reduces the number Na of power supplies in operation selectively to 4 or 3. More specifically, when the current number Na of power supplies in operation is 4, the controller 52 reduces the number Na of power supplies in operation to 3 in response to the number X of movable bodies in the target power feed area A being less than or equal to 18, which is the first threshold TH1. When the current number Na of power supplies in operation is 3, the controller 52 increases the number Na of power supplies in operation to 4 in response to the number X of movable bodies in the target power feed area A being greater than or equal to 20, which is the second threshold TH2.

In this example, the first threshold TH1 and the second threshold TH2 are respectively set to 5 and 8 when the controller 52 increases or reduces the number Na of power supplies in operation selectively to 3 or 2. More specifically, when the current number Na of power supplies in operation is 3, the controller 52 reduces the number Na of power supplies in operation to 2 in response to the number X of movable bodies in the target power feed area A being less than or equal to 5, which is the first threshold TH1. When the current number Na of power supplies in operation is 2, the controller 52 increases the number Na of power supplies in operation to 3 in response to the number X of movable bodies in the target power feed area A being greater than or equal to 8, which is the second threshold TH2.

In this example, the controller 52 does not increase or reduce the number Na of power supplies in operation selectively to 2 or 1. Further, the controller 52 also does not increase or reduce the number Na of power supplies in operation selectively to 1 or 0. In other words, when the current number Na of power supplies in operation is 2 or 1, the first threshold TH1 is not set in this example. When the current number Na of power supplies in operation is 1 or 0, the second threshold TH2 is not set.

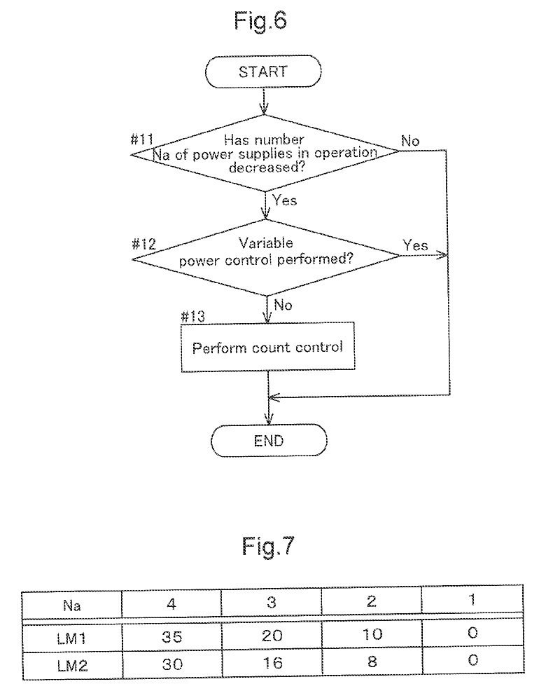

A control process performed by the movable body control system 6 will be described below with reference to FIG. 6. FIG. 6 is a flowchart of an example control process performed by the movable body control system 6.

As shown in FIG. 6, the movable body control system 6 first determines whether the number Na of power supplies in operation has decreased (step #11). When the number Na of power supplies in operation has not decreased (No in step #11), the movable body control system 6 ends the control process.

When the number Na of power supplies in operation has decreased (Yes in step #11), the movable body control system 6 determines whether the number Na of power supplies in operation has decreased under the variable power control (step #12). When the number Na of power supplies in operation has decreased under the variable power control (Yes in step #12), the movable body control system 6 ends the control process.

When the number Na of power supplies in operation has decreased independently of the variable power control (No in step #12), the movable body control system 6 determines that one or more of the N power supplies 41 are in a non-operable state in which one or more of the N power supplies 41 are unable to supply power to the feed lines 3, and performs a count control (step #13). The count control limits the number of movable bodies 1 that can enter the power feed area A. In this example, the movable body control system 6 limits, in the count control, the number of movable bodies 1 that can enter a power feed area A including the feed line 3 connected to a power supply 41 in the non-operable state among the multiple power feed areas A.

In this example, as described above, the movable body control system 6 performs the count control to limit the number of movable bodies 1 that can enter the power feed area A in response to a decrease in the number Na of power supplies in operation resulting from one or more of the N power supplies 41 being unable to supply power to the feed line 3. The movable body control system 6 does not perform the count control in response to a decrease in the number Na of power supplies in operation under the variable power control.

In the example shown in FIG. 7, a first limit LM1 and a second limit LM2 are set for each number Na of power supplies in operation. The first limit LM1 is the maximum number of movable bodies 1 that can enter the power feed area A. The second limit LM2 is less than the first limit LM1. The second limit LM2 is set to remove a specific movable body 1 (e.g., a movable body 1 on standby without performing an operation) from the power feed area A when the number of movable bodies 1 in the power feed area A approaches the first limit LM1.

In this example, when the number Na of power supplies in operation has not decreased and is 4, the first limit LM1 is set to 35. This indicates that the maximum number of movable bodies 1 that can be in the power feed area A is 35. Thus, when the number Na of power supplies in operation is 4, or in other words, when the number Na of power supplies in operation has not decreased, the number of movable bodies 1 that can enter the power feed area A is limited to less than or equal to 35. When the number Na of power supplies in operation is 4, the second limit LM2 is set to 30.

In this example, when one power supply 41 is in the non-operable state and the number Na of power supplies in operation is 3, the first limit LM1 and the second limit LM2 are respectively set to 20 and 16. When two power supplies 41 are in the non-operable state and the number Na of power supplies in operation is 2, the first limit LM1 and the second limit LM2 are respectively set to 10 and 8.

When three power supplies 41 are in the non-operable state and the number Na of power supplies in operation is 1, the first limit LM1 and the second limit LM2 are both set to zero. In this case, the movable bodies 1 are prevented from entering the power feed area A. The movable bodies 1 are all removed from the power feed area A.

### Other Embodiments

(1) In the above embodiment, the movable bodies 1 are ceiling-hung transport vehicles that travel along the travel path P as being guided along the travel rails 2 hung from the ceiling. However, the structure is not limited to this example. For example, the movable bodies 1 may be tracked transport vehicles that travel along rails on the floor surface.

(2) In the above embodiment, the power receivers 13 in the movable bodies 1 receive power from the feed lines 3 contactlessly. However, the structure is not limited to this example. The power receivers 13 in the movable bodies 1 may be in contact with the feed lines 3 to receive power.

(3) In the above embodiment, each power supply device 4 includes N power supplies 41 (N is an integer greater than or equal to 2), and the corresponding controller 52 increases or reduces the number Na of power supplies 41 in operation in the variable power control to increase or reduce power supplied from the power supply device 4 to the corresponding feed line 3. However, the structure is not limited to this example. Each power supply device 4 may include one power supply 41. In this structure, the corresponding controller 52 may increase or reduce power supplied from the power supply 41 to the corresponding feed line 3 in the variable power control.

(4) In the above embodiment, the power feeder 100 includes the multiple control systems 5 and the movable body control system 6. However, the structure is not limited to this example. For example, the multiple control systems 5 and the movable body control system 6 may form an integral control system.

(5) In the above embodiment, each count obtainer 51 obtains the count information indicating the number X of movable bodies from the movable body control system 6. However, the structure is not limited to this example. For example, each count obtainer 51 may also use, for example, a camera or a sensor to obtain the count information indicating the number X of movable bodies.

(6) In the above embodiment, when the number Na of power supplies in operation has decreased independently of the variable power control, the movable body control system 6 determines that one or more of the N power supplies 41 are in the non-operable state and performs the count control. However, the structure is not limited to this example. For example, each control system 5 may monitor the states of the power supplies 41, and the movable body control system 6 may obtain the states of the power supplies 41 from the control system 5 to determine that one or more of the N power supplies 41 are in the non-operable state.

(7) In the above embodiment, each movable body 1 includes the power receiver 13 that receives power from the feed lines 3 contactlessly, and moves with the power received by the power receiver 13. However, the structure is not limited to this example. For example, each movable body 1 may further include a power storage that stores the power received by the power receiver 13, and may move with the power stored in the power storage. In this structure, a movable body 1 with a large amount of charge in the power storage may be excluded from the number X of movable bodies when the variable power control is performed.

(8) The structure described in each of the above embodiments may be combined with other structures described in the other embodiments unless any contradiction arises. The embodiments described herein are merely illustrative in all aspects and may be modified variously as appropriate without departing from the spirit and scope of the present disclosure.

### Overview of Embodiments

An overview of the power feeder described above is provided below.

A power feeder includes at least one feed line extending along a travel path for a plurality of movable bodies to feed power to the plurality of movable bodies, at least one power supply device connected to the at least one feed line to supply power to the at least one feed line, and at least one control system that controls the at least one power supply device. The at least one control system includes a count obtainer that obtains count information indicating a number of movable bodies in at least one power feed area that is an area in which the at least one feed line is disposed in the travel path, and a controller that performs, based on the count information, variable power control to reduce power supplied from the at least one power supply device to the at least one feed line in response to a decrease in the number of movable bodies in the at least one power feed area and increase power supplied from the at least one power supply device to the at least one feed line in response to an increase in the number of movable bodies in the at least one power feed area.

In this structure, when the number of movable bodies in the power feed area increases or decreases, power supplied from the power supply device to the feed line can be appropriately adjusted through the variable power control. The structure allows the power feeder to consume less power than, for example, a structure in which power supplied from the power supply device to the feed line is set based on the maximum number of movable bodies that can be in the power feed area.

In the variable power control, the controller may reduce power supplied from the at least one power supply device to the at least one feed line in response to the number of movable bodies in the at least one power feed area being less than or equal to a predetermined first threshold and increase power supplied from the at least one power supply device to the at least one feed line in response to the number of movable bodies in the at least one power feed area being greater than or equal to a predetermined second threshold. The first threshold may be less than the second threshold.

This structure can prevent power supplied from the power supply device to the feed line from being increased or reduced frequently.

The at least one power supply device may include N power supplies, where N is an integer greater than or equal to 2. In the variable power control, the controller may increase or reduce a number of power supplies in operation to increase or reduce power supplied from the at least one power supply device to the at least one feed line, where the number of power supplies in operation is, among the N power supplies, a number of power supplies supplying power to the at least one feed line.

This structure allows the process for the variable power control performed by the control system to be simpler.

In the above structure, the power feeder may further include a movable body control system that controls the plurality of movable bodies. The movable body control system may perform count control to limit a number of movable bodies entering the at least one power feed area in response to a decrease in the number of power supplies in operation resulting from one or more of the N power supplies being unable to supply power to the at least one feed line. The movable body control system may not perform the count control in response to a decrease in the number of power supplies in operation under the variable power control.

In this structure, when one or more of the power supplies are unable to supply power to the feed line, the count control is performed to limit the number of movable bodies that can enter the power feed area. This reduces the likelihood that the number of movable bodies in the power feed area increases and the movable bodies thus receive insufficient power.

When the number of movable bodies in the power feed area increases during the variable power control, the number of power supplies in operation is increased to appropriately supply power to all the movable bodies in the power feed area.

In the power feeder, the at least one power line may include a plurality of feed lines extending along the travel path, the at least one power supply device may include a plurality of power supply devices connected to the plurality of respective feed lines, and the at least one control system may include a plurality of control systems that control the plurality of respective power supply devices. The at least one power feed area may include a plurality of power feed areas defined to correspond to the plurality of respective feed lines. The controllers in the plurality of control systems may perform the variable power control independently of one another, and may not perform the variable power control in a power feed area in which, among the plurality of power feed areas, an increase or a decrease in a number of movable bodies per unit time is greater than or equal to a predetermined variable threshold.

This structure allows power to be supplied appropriately based on the number of movable bodies in each of the power feed areas.

This structure also reduces the likelihood that power cannot be supplied quickly enough in response to a sudden increase in the number of movable bodies in the power feed area and the movable bodies thus receive insufficient power.

The power feeder may further include a movable body control system that controls the plurality of movable bodies. The count obtainer may obtain the count information from the movable body control system. The controller may not perform the variable power control until a predetermined set time elapses from activation of the movable body control system.

The movable body control system may inaccurately determine the number of movable bodies before the set time elapses from the activation of the movable body control system. The structure described above reduces the likelihood that power cannot be supplied to the movable bodies appropriately under the variable power control based on such inaccurate information.

### INDUSTRIAL APPLICABILITY

The technique according to one or more embodiments of the present disclosure is applicable to a power feeder including a feed line extending along a travel path for multiple movable bodies to feed power to the multiple movable bodies and a power supply device connected to the feed line to supply power to the feed line.

What is claimed is:

1. A power feeder, comprising:
at least one feed line extending along a travel path for a plurality of movable bodies to feed power to the plurality of movable bodies;
at least one power supply device connected to the at least one feed line to supply power to the at least one feed line; and
at least one control system configured to control the at least one power supply device, the at least one control system comprising:
a count obtainer configured to obtain count information indicating a number of movable bodies in at least one power feed area, wherein the at least one power feed area is an area in which the at least one feed line is disposed in the travel path, and
a controller configured to perform, based on the count information, variable power control to reduce power supplied from the at least one power supply device to the at least one feed line in response to a decrease in the number of movable bodies in the at least one power feed area and to increase power supplied from the at least one power supply device to the at least one feed line in response to an increase in the number of movable bodies in the at least one power feed area.

2. The power feeder according to claim 1, wherein:
in the variable power control, the controller reduces power supplied from the at least one power supply device to the at least one feed line in response to the number of movable bodies in the at least one power feed area being less than or equal to a predetermined first threshold and increases power supplied from the at least one power supply device to the at least one feed line in response to the number of movable bodies in the at least one power feed area being greater than or equal to a predetermined second threshold, and
the first threshold is less than the second threshold.

3. The power feeder according to claim 1, wherein:
the at least one power supply device comprises N power supplies, where N is an integer greater than or equal to 2, and
in the variable power control, the controller increases or reduces a number of power supplies in operation to increase or reduce power supplied from the at least one power supply device to the at least one feed line, where the number of power supplies in operation is, among the N power supplies, a number of power supplies supplying power to the at least one feed line.

4. The power feeder according to claim 3, further comprising:
a movable body control system configured to control the plurality of movable bodies,
wherein the movable body control system performs count control to limit a number of movable bodies entering the at least one power feed area in response to a decrease in the number of power supplies in operation resulting from one or more of the N power supplies being unable to supply power to the at least one feed line, and
wherein the movable body control system does not perform the count control in response to a decrease in the number of power supplies in operation under the variable power control.

5. The power feeder according to claim 1, wherein:
the at least one power line comprises a plurality of feed lines extending along the travel path, the at least one power supply device comprises a plurality of power supply devices connected to the plurality of respective feed lines, and the at least one control system comprises a plurality of control systems configured to control the plurality of respective power supply devices,
the at least one power feed area comprises a plurality of power feed areas defined to correspond to the plurality of respective feed lines, and
the controllers in the plurality of control systems perform the variable power control independently of one another, and do not perform the variable power control in a power feed area in which, among the plurality of power feed areas, an increase or a decrease in a number of movable bodies per unit time is greater than or equal to a predetermined variable threshold.

6. The power feeder according to claim 1, further comprising:
a movable body control system configured to control the plurality of movable bodies,
wherein the count obtainer obtains the count information from the movable body control system, and
wherein the controller does not perform the variable power control until a predetermined set time elapses from activation of the movable body control system.
